(19) United States
(12) Patent Application Publication
(10) Pub. No.: US 2009/0065947 A1
(43) Pub. Date: Mar. 12, 2009

(54) Semiconductor device having circularly connected plural pads via through holes and method of evaluating the same

(75) Inventor: Kenshi Kudou, Kumamoto (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/219,589

(22) Filed: Jul. 24, 2008

(30) Foreign Application Priority Data
Sep. 11, 2007 (JP) 2007-235011

(51) Int. Cl. H01L 23/48; H01L 21/66

(52) U.S. Cl. 257/774; 438/17; 257/E21.521; 257/E23.01

(57) ABSTRACT

A semiconductor device includes a plurality of wiring layers, a plurality of via layers, and a plurality of electrode pads. The electrode pads are circularly connected to each other through the wiring layers and the via layers.

### BACKGROUND OF THE INVENTION

1. Field of the Invention

The present invention relates to a semiconductor device and a method of evaluating the semiconductor device.

2. Description of Related Art

In evaluating the characteristics of a semiconductor device, conduction is checked by measuring the resistance of a contact hole or a through hole. As a semiconductor device capable of evaluating the conducting properties of such a contact hole and a through hole, those described in Patent Documents 1 and 2 have hitherto been known.

Patent Document 1 describes, as a related art, a check pattern of a semiconductor device in a case where through holes are connected in series. In a semiconductor device 40 shown in FIG. 12, an upper layer interconnect 111 of the same layer as a terminal 131 is electrically connected to a lower layer interconnect 121 and is further connected to an upper layer interconnect 112 via a through hole 102. Similarly, via through holes 103 to 106, a lower layer interconnect 122, an upper layer interconnect 113, a lower layer interconnect 123 and an upper layer interconnect 114 are connected respectively, whereby a terminal 131 and the terminal 132 are connected.

Patent Document 2 describes a semiconductor device in which a plurality of conductive interconnects having different resistance values are provided by being stacked via interlayer dielectrics and both ends of each of the conductive interconnects are connected parallel to adjacent conductive interconnects in the stacking direction. The evaluation of the semiconductor device is performed by applying a voltage across both ends of the conductive interconnect, making a comparison between a current value made ready beforehand and the result of the measurement, and identifying a broken line. This arrangement enables a plurality of TEGs (Test Element Groups) to be vertically stacked and furthermore simultaneous measurements for the plurality of TEGs to be made by using common pads. For this reason, the TEG area and the pad area can be reduced.

[Patent Document 1] Japanese Patent Laid-Open No. 2001-144253

[Patent Document 2] Japanese Patent Laid-Open No. 2005-223227

### SUMMARY OF THE INVENTION

However, because in the semiconductor device 40 explained in FIG. 12 only measurement of the resistance between the terminal 131 and the terminal 132 is performed, it has been difficult to measure the resistance of each of the plurality of through holes formed in different layers connected in series between the terminal 131 and the terminal 132. Furthermore, in order to simultaneously measure the resistance of two through holes formed in different layers, two terminals are used for one through hole, thereby posing the problem that a region for forming the terminals is further required.

In the semiconductor device described in Patent Document 2, the dentification of a broken line is performed for a plurality of conductive interconnects. For this reason, it has been difficult to detect interconnect short circuits, which cause failures in semiconductor devices in addition to broken lines.

As shown in FIG. 13, general measurement of the through hole resistance of a semiconductor device is performed by arranging electrode pads 56 and through-hole chains R on a straight line. A description will be given below of, for example, the measurement of the through hole resistance in a case where a semiconductor device 50 has a five-layer aluminum interconnects.

FIGS. 14A and 14B show an A-A′ sectional view and a B-B′ sectional view, respectively, of FIG. 13. In the semiconductor device 50, upon an aluminum interconnect 571 of the lowest layer there are formed an aluminum interconnect 572, an aluminum interconnect 573, an aluminum interconnect 574, and an aluminum interconnect 575 of the highest layer. The aluminum interconnect 575 of the highest layer in which a check pattern is formed, functions as the electrode pad 56. Aluminum interconnects of each layer are connected via a plug 58. In each of the aluminum interconnect layers, a through-hole chain R in which a plurality of through holes are connected in chain shape, is formed.

An electrode pad 56a and an electrode pad 56b are connected by a first through-hole chain R1, and the electrode pad 56b and an electrode pad 56c are connected by a second through-hole chain R3. An electrode pad 56d and an electrode pad 56e are connected by a third through-hole chain R3, and the electrode pad 56e and an electrode pad 56f are connected by a fourth through-hole chain R4.

Next, the evaluation method will be described by using FIGS. 15 and 16. A through hole resistance measuring instrument (not shown) is mainly composed of three probes, i.e., a probe 591, a probe 592 and a probe 593, a DC power supply, ammeters 1 and 2, and switches 1 and 2.

First, the probe 591, the probe 592 and the probe 593 are brought into contact with the electrode pad 56a, the electrode pad 56b and the electrode pad 56c, respectively. The switch 1 is turned on and the switch 2 is turned off (FIG. 15). By use of the power supply, the voltage to the probe 592 is set at zero and the voltage to the probe 591 is applied so that this voltage becomes Ev, and a current Ia flowing through the probe 591 at this time is measured by using the ammeter 1. The resistance Rab of the first through-hole chain R1 is found as given by the following equation (1).

Rab=Ev/Ia (1)

If the number of through holes in one through-hole chain R1 is denoted by N₁, then the resistance r (average value) per through hole is found as given by the following equation (2).

rab=Rab/N₁ (2)

Next, with the probe 591, the probe 592 and the probe 593 kept in contact with the electrode pad 56a, the electrode pad 56b and the electrode pad 56c, respectively, the switch 1 is turned off and the switch 2 is turned on. By use of the power supply, the voltage to the probe 592 is set at zero and the voltage to the probe 593 is applied so that this voltage becomes Ev, and a current Ic flowing through the probe 593 at this time is measured by using the ammeter 2. The resistance Rbc of the second through-hole chain R2 is found as given by the following equation (3).

Rbc=Ev/Ic (3)

If the number of through holes in one through-hole chain R2 is denoted by N₂, then the resistance r (average value) per through hole is found as given by the following equation (4).

rbc=Rbc/N₂ (4)

With the probe 591, the probe 592 and the probe 593 kept in contact with the electrode pad 56d, the electrode pad 56e and the electrode pad 56f, respectively, the resistance Rde of the third through-hole chain R3 and the resistance Ref of the fourth through-hole chain R4 are also found by the same operation as described above.

In this manner, the resistance of each of the through-hole chains is found and the resistance measurement of each through hole is performed.

However, in such a semiconductor device, during the measurement of Rab and Rbc, the electrode pad 56a, the electrode pad 56b and the electrode pad 56c are used and the electrode pad 56d, the electrode pad 56e and the electrode pad 56f are not used. On the other hand, during the measurement of Rde and Ref, the electrode pad 56d, the electrode pad 56e and the electrode pad 56f are used and the electrode pad 56a, the electrode pad 56b and the electrode pad 56c are not used. That is, six electrode pads are used to measure four kinds of resistance R. When three electrode pads are used by use of three probes, none of the remaining three electrode pads is used. In this condition, therefore, the area occupied by electrode pads on which a check pattern is formed increases (that is, a useless area is required) and this poses the problem that particularly, further scaledown and multilayer interconnection of semiconductor devices are impossible.

A semiconductor device includes a multilayer interconnect structure in which an interconnect layer and a via layer are alternately stacked, and a plurality of through-hole chains constructed by that a plurality of through holes formed in the via layer and interconnects provided in the through hole and in an upper part and a lower part of the via layer are connected each other. The through-hole chains provided in different via layers are connected so as to form an annulus via electrode pads so that that resistance of two through-hole chains provided in different via layers is simultaneously measurable by using the electrode pads.

In this semiconductor device, the through-hole chains having different via layers are connected so as to form an annulus via electrode pads, whereby the through-hole chains share one electrode pad. Therefore, this makes it possible to reduce the number of electrode pads used in the measurement of the resistance of a plurality of through-hole chains having different via layers and to reduce the area of a check pattern.

A method of evaluating this semiconductor device includes three or more electrode pads for measuring the resistance of the through-hole chains, and in that among the electrode pads, the voltage of a first electrode pad is set at 0, a prescribed voltage is simultaneously applied to a second electrode pad and a third electrode pad, and a current that flows due to the application is measured, whereby the resistance of the through-hole chain connected between the first electrode pad and the second electrode pad and the resistance of the through-hole chain connected between the first electrode pad and the third electrode pad are simultaneously measured.

In a method of evaluating the semiconductor device, the first electrode pad, the second electrode pad and the third electrode pad are used, the voltage of the first electrode pad is set at 0, a prescribed voltage is simultaneously applied to the second electrode pad and the third electrode pad, and a current that flows due to the application is measured. In a case where through-hole chains and electrode pads are annularly connected, for example, when the voltage of the first electrode pad is set at 0 and a voltage V is applied to the second electrode pad, a current flowing directly from the power supply and a current circulating through the annulus also flow through the second electrode pad. In such a case, it becomes difficult to accurately measure the current flowing through the second electrode pad.

In contrast to this, in the method of evaluating the semiconductor device according to the present invention, the voltage of the first electrode pad is set at 0, a prescribed voltage is simultaneously applied to the second electrode pad and the third electrode pad. Therefore, currents flowing by circulating through the second electrode pad and the third electrode pad cancel each other out, and only currents flowing through the second electrode pad and the third electrode pad directly from the power supply are measured. For this reason, accurate current measurements become possible simultaneously for each of the second electrode pad and the third electrode pad and it is possible to simultaneously measure the resistance of the through-hole chain connected between the first electrode pad and the second electrode pad and the resistance of the through-hole chain connected between the first electrode pad and the third electrode pad. Therefore, the measurement time can be shortened.

According to the present invention, a semiconductor device having a structure which is such that the resistance of through-hole chains having different via layers is measured and the area of a check pattern for resistance measurement is reduced and a method of evaluating a semiconductor device in which the measurement time is shortened are realized.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a top view showing a first exemplary embodiment of a semiconductor device according to the present invention;

FIG. 2 is a sectional view showing the first exemplary embodiment of a semiconductor device according to the present invention;

FIG. 3 is a sectional view showing the first exemplary embodiment of a semiconductor device according to the present invention;

FIG. 4 is a sectional view showing the first exemplary embodiment of a semiconductor device according to the present invention;

FIG. 5 is a sectional view showing the first exemplary embodiment of a semiconductor device according to the present invention;

FIG. 6 is a sectional view showing the first exemplary embodiment of a semiconductor device according to the present invention;

FIG. 7 is a sectional view showing the first exemplary embodiment of a semiconductor device according to the present invention;

FIG. 8 is a top view showing a way to use the first exemplary embodiment of a semiconductor device according to the present invention;

FIG. 9 is a top view showing a way to use the first embodiment of a semiconductor device according to the present invention;

FIGS. 10A to 10C are top views showing a second exemplary embodiment of a semiconductor device according to the present invention;

FIGS. 11A to 11E are top views showing a third exemplary embodiment of a semiconductor device according to the present invention;

FIG. 12 is a top view showing a semiconductor device of a related art;

FIG. 13 is a top view showing a semiconductor device of a related art;

FIGS. 14A and 14B are sectional views showing a semiconductor device of a related art;

FIG. 15 is a top view showing how to use a semiconductor device of a related art; and

FIG. 16 is a top view showing how to use a semiconductor device of a related art.

### DETAILED DESCRIPTION OF THE EXEMPLARY EMBODIMENTS

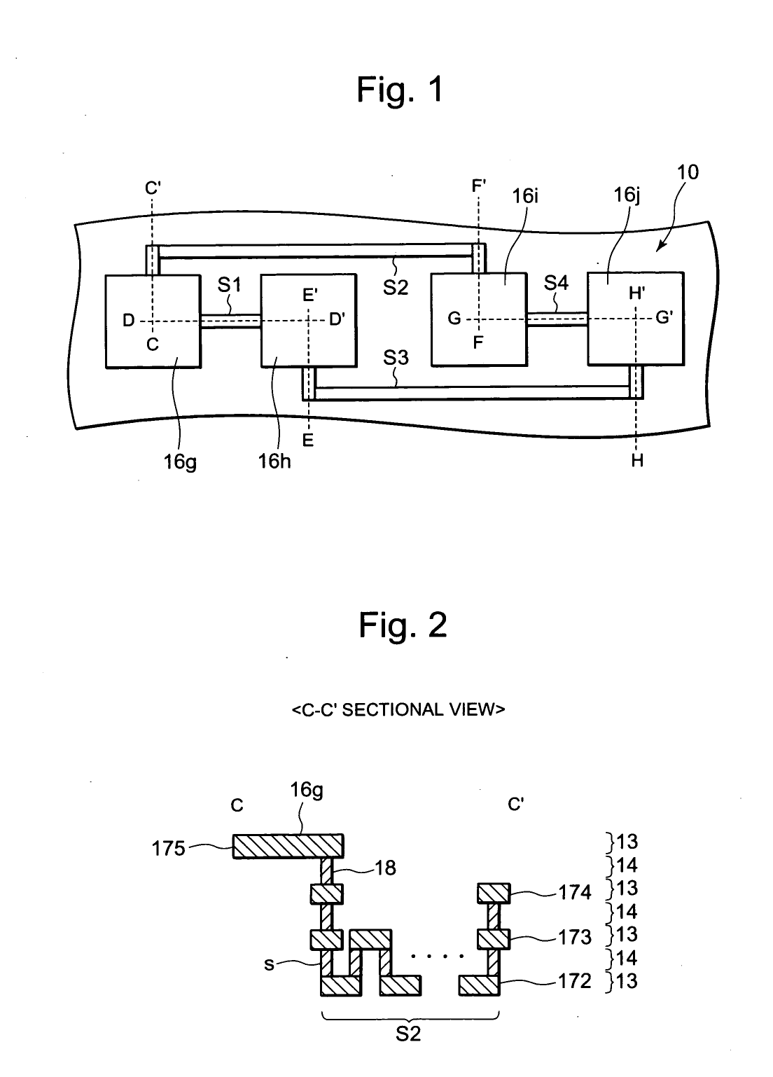

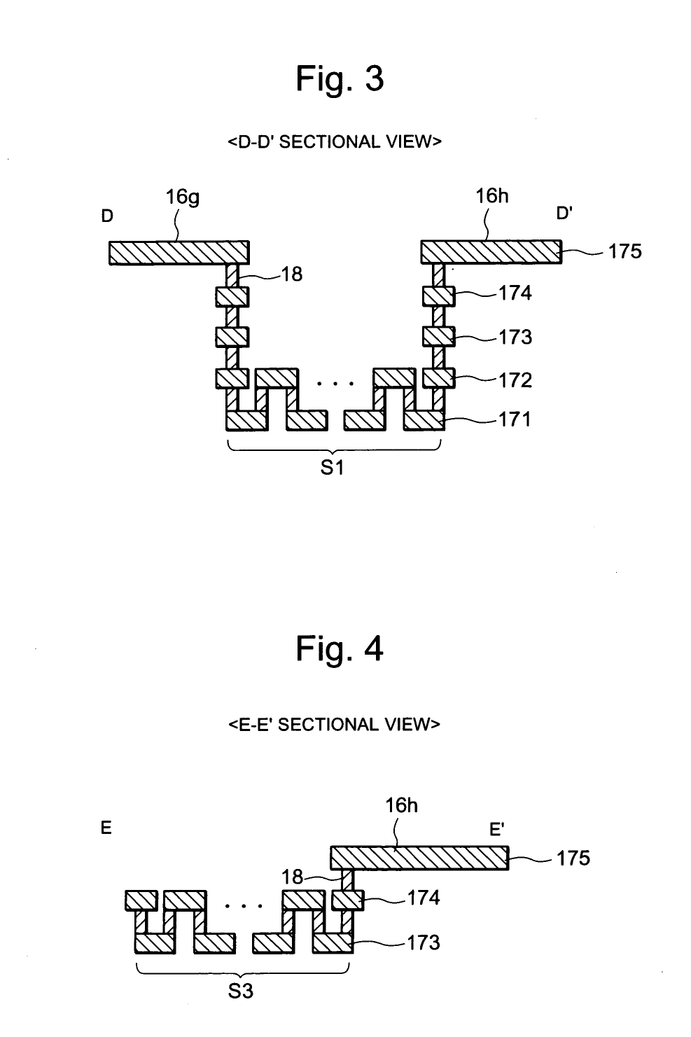

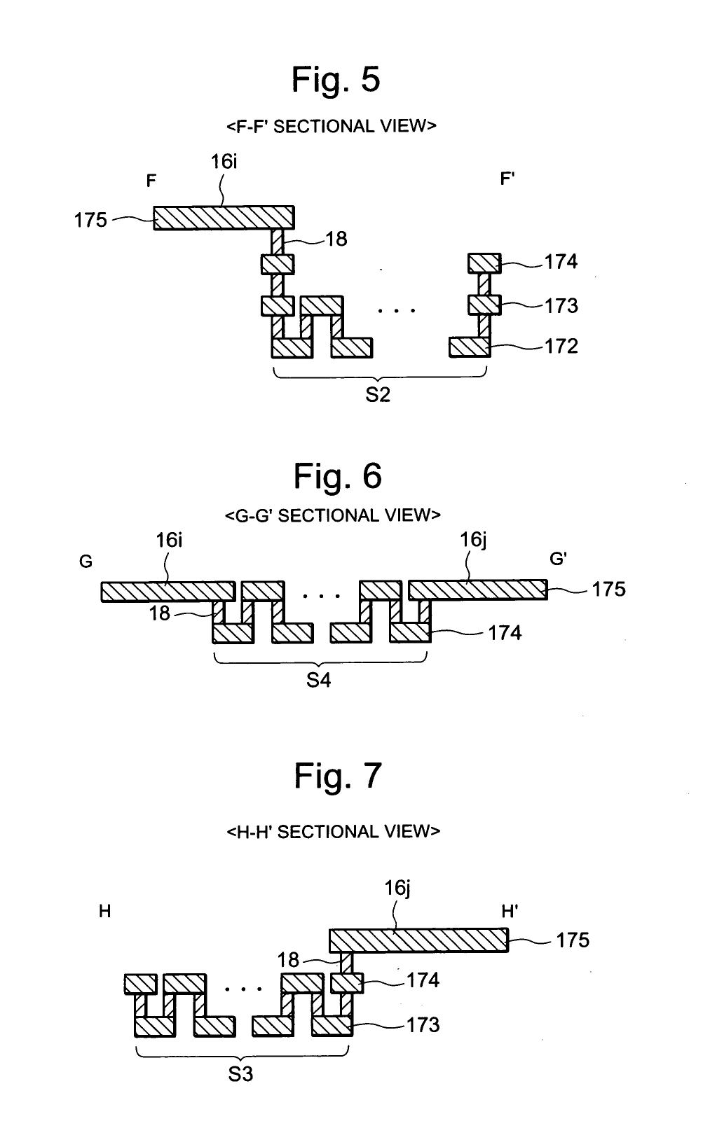

FIGS. 1 to 7 are top views or sectional views showing a first exemplary embodiment of the semiconductor device according to the present invention. The C-C′ sectional view, D-D′ sectional view, E-E′ sectional view, F-F′ sectional view, G-G′ sectional view and H-H′ sectional view of FIG. 1 are shown in FIG. 2, FIG. 3, FIG. 4, FIG. 5, FIG. 6 and FIG. 7, respectively.

A semiconductor device 10 has a five-layer aluminum interconnect in which an interconnect layer 13 and a via layer 14 are alternately stacked.

The interconnect layer 13 is such that upon an aluminum interconnect 171 of the lowest layer are formed an aluminum interconnect 172, an aluminum interconnect 173, an aluminum interconnect 174, and an aluminum interconnect 175 in this order. A check pattern is formed on the aluminum interconnect 175 of the highest layer and functions as an electrode pad 16 (16g, 16h, 16i, 16j). The check pattern is formed at the same time with the formation of device interconnects as a pattern for checking the device characteristics of a product wafer and is used to check the characteristics before dicing.

In each of the via layers 14, a plurality of through holes s are formed. The number of through holes s may differ from a via layer 14 to a via layer 14. These through holes s and aluminum interconnects provided in an upper part and a lower part of each of the via layers 14 are connected, whereby a through-hole chain S is formed. Both ends of the through-hole chain S are each connected to the electrode pad 16 via an aluminum interconnect and a via layer. A plug 18 is formed below the electrode pad 16 and is connected to the through-hole chain S. The plurality of through holes s formed in the single via layer 14 and the aluminum interconnects provided in an upper part and a lower part of the via layer 14 are connected, whereby the through-hole chain S is formed. That is, through-hole chains S formed in different single via layers 14 are connected via the electrode pad 16. As a result of this, through-hole chains S having different via layers are connected so as to form an annulus via the electrode pad 16 and, therefore, it is possible to measure resistance for each of the through-hole chains S having different via layers. In other words, because the through holes s that a through-hole chain S has are formed in a single via layer 14, it is possible to measure the resistance of the through-hole chain S for each of the via layers 14.

The C-C′ sectional view, D-D′ sectional view, E-E′ sectional view, F-F′ sectional view, G-G′ sectional view and H-H′ sectional view of FIG. 1 will be described in detail below.

As shown in FIGS. 2 and 5, a plurality of through holes s formed in the via layer 14 between the aluminum interconnects 172 and 173 are connected to the aluminum interconnects 172 and 173 in chain shape, whereby a through-hole chain S2 is formed. On end of the through-hole chain S2 is connected to the electrode pad 16g, and the other end thereof is connected to the electrode pad 16i.

As shown in FIG. 3, a plurality of through holes s formed in the via layer 14 between the aluminum interconnects 171 and 172 are connected to the aluminum interconnects 171 and 172 in chain shape, whereby a through-hole chain S1 is formed. On end of the through-hole chain S1 is connected to the electrode pad 16g, and the other end thereof is connected to the electrode pad 16h.

As shown in FIGS. 4 and 7, a plurality of through holes s formed in the via layer 14 between the aluminum interconnects 173 and 174 are connected to the aluminum interconnects 173 and 174 in chain shape, whereby a through-hole chain S3 is formed. On end of the through-hole chain S3 is connected to the electrode pad 16h, and the other end thereof is connected to the electrode pad 16j.

As shown in FIG. 6, a plurality of through holes s formed in the via layer 14 between the aluminum interconnects 174 and 175 are connected to the aluminum interconnects 174 and 175 in chain shape, whereby a through-hole chain S4 is formed. On end of the through-hole chain S4 is connected to the electrode pad 16i, and the other end thereof is connected to the electrode pad 16j.

As shown in FIG. 1, in this manner, the electrode pad 16g and the electrode pad 16h are connected by the first through-hole chain S1, the electrode pad 16g and the electrode pad 16i are connected by the second through-hole chain S2, the electrode pad 16h and the electrode pad 16j are connected by the third through-hole chain S3, and the electrode pad 16i and the electrode pad 16j are connected by the fourth through-hole chain S4. In other words, the through-hole chains S are connected so as to form an annulus via the electrode pad 16.

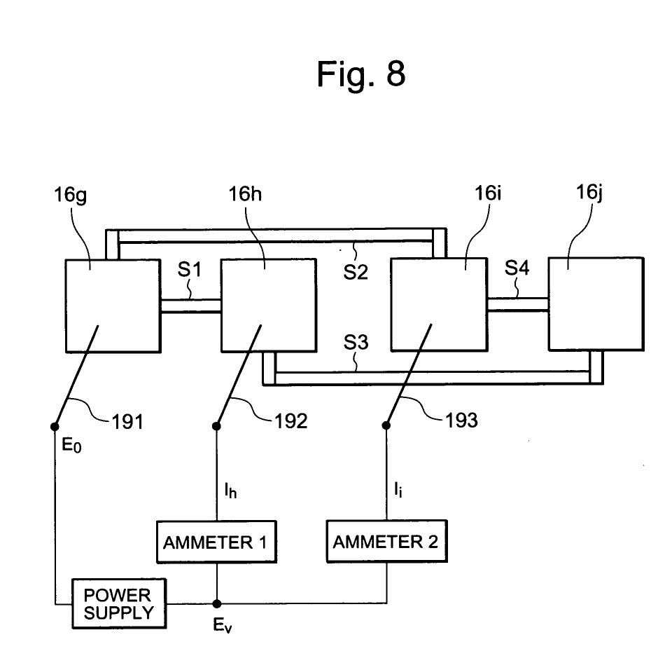

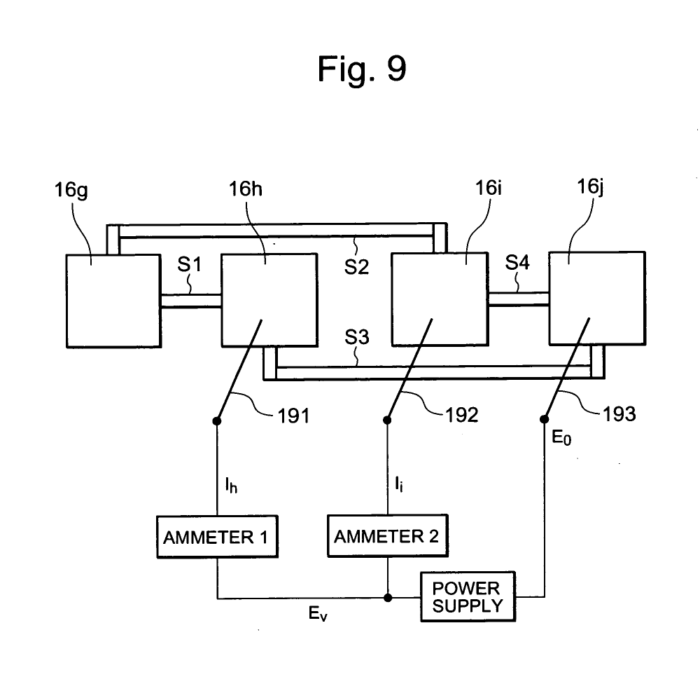

Next, the evaluation method will be described by using FIGS. 8 and 9. A through-hole resistance measuring instrument (not shown) is composed mainly of three probes, i.e., a probe 191, a probe 192 and a probe 193, a DC power supply, ammeters, and switches. The semiconductor device 10 has four electrode pads for measuring the resistance of the through-hole chain S.

First, the probe 191, the probe 192 and the probe 193 are brought into contact with an electrode pad 16g, an electrode pad 16h and an electrode pad 16i, respectively. By use of the power supply, the voltage to the electrode pad 16g is set at zero and the voltage to the electrode pad 16h and the electrode pad 16i is simultaneously applied so that this voltage becomes Ev, and currents Ih and Ii flowing through the probe 192 and the probe 193 due to this application are measured by using the ammeter 1 and the ammeter 2, respectively (FIG. 8). The resistance Rgh of the first through-hole chain S1 connected between the electrode pad 16g and the electrode pad 16h and the resistance Rgi of the second through-hole chain S2 connected between the electrode pad 16g and the electrode pad 16i are found by the following equations (5) and (6), respectively.

Rgh=Ev/Ih (5)

Rgi=Ev/Ii (6)

If the numbers of through holes s in one through-hole chain S₁, S₂ are denoted by N₁, N₂ (N is an integer of 2 or more), respectively, then the resistance r (average value) per through hole s is found as given by the following equations (7) and (8), respectively. This is because a plurality of through holes s formed in a single via layer 14 is considered to take on a similar resistance value for each via layer 14.

rgh=Rgh/N₁ (7)

rgi=Rgi/N₂ (8)

Next, the probe 191, the probe 192 and the probe 193 are brought into contact with the electrode pad 16h, the electrode pad 16i and an electrode pad 16j, respectively. By use of the power supply, the voltage to the electrode pad 16j is set at zero and the voltage to the electrode pad 16h and the electrode pad 16i is simultaneously applied so that this voltage becomes Ev, and currents Ih and Ii flowing through the probe 191 and the probe 192 due to this application are measured by using the ammeter I and the ammeter 2, respectively (FIG. 9). The resistance Rhj of the third through-hole chain S3 connected between the electrode pad 16h and the electrode pad 16j and the resistance Rij of the fourth through-hole chain S4 connected between the electrode pad 16i and the electrode pad 16j are found by the following equations (9) and (10), respectively.

Rhj=Ev/Ih (9)

Rij=Ev/Ii (10)

If the numbers of through holes s in one through-hole chain S3, S4 are denoted by N₃, N₄, respectively, then the resistance r (average value) per through hole s is found as given by the following equations (11) and (12), respectively. This is because a plurality of through holes s formed in a single via layer 14 are considered to take on a similar resistance value for each via layer 14.

rhj=Rhj/N₃ (11)

rij=Rij/N₄ (12)

In this manner, the resistance r per through hole s is found from the resistance R of each of the through-hole chains S. In this embodiment, four through-hole chains S are connected so as to form an annulus via four electrode pads 16, whereby two different through-hole chains S share one electrode pad 16 via four electrode pads 16. Therefore, the number of electrode pads used in the measurement of the resistance of four through-hole chains can be restricted to four as a whole and the area of the check pattern can be reduced. Furthermore, because the through holes s that the through-hole chain S has are formed in different single via layers 14, the through-hole chains S formed from different via layers 14 are connected to the electrode pad 16 shared by the through-hole chains S and hence it is possible to measure the resistance of the through-hole chains S for each via layer 14.

Furthermore, in the semiconductor device 50 of the related art, six electrode pads are used to measure four kinds of resistance R and when three probes are used for three electrode pads, the remaining three pads are not used. In contrast to this, in the semiconductor device 10 in this embodiment, four electrode pads are used to measure four kinds of resistance R, and two kinds of resistance R can be simultaneously measured by using three probes. Therefore, in such a condition, the area occupied by an electrode pad on which a check pattern is formed can be reduced, and in a trial calculation, a reduction of the area by 8% to 30% or so becomes possible. As a result of this, further scaledown and multilayer interconnection of semiconductor devices become possible.

In a usual method of evaluating a semiconductor device, in a case where through-hole chains and electrode pads are connected, for example, when the voltage of the first electrode pad is set at 0 and a voltage V is applied to the second electrode pad, a current flowing directly from the power supply and a current circulating through the annulus also flow through the second electrode pad. In such a case, it becomes difficult to accurately measure the current flowing through the second electrode pad. In contrast to this, in the method of evaluating the semiconductor device according to the present invention, the voltage of the electrode pad 16g is set at 0, a prescribed voltage is simultaneously applied to the electrode pad 16h and the electrode pad 16i. Therefore, currents flowing by circulating through the electrode pad 16h and the electrode pad 16i cancel each other out, and only currents due to the voltage Ev flow through the electrode pad 16h and the electrode pad 16i and hence no effect is exerted on current measurement. For this reason, accurate current measurements become possible simultaneously for each of the electrode pad 16h and the electrode pad 16i and it is possible to simultaneously measure the resistance of the through-hole chain S1 connected between the electrode pad 16g and the electrode pad 16h and the resistance of the through-hole chain S2 connected between the electrode pad 16g and the electrode pad 16i. Therefore, the measurement time can be shortened.

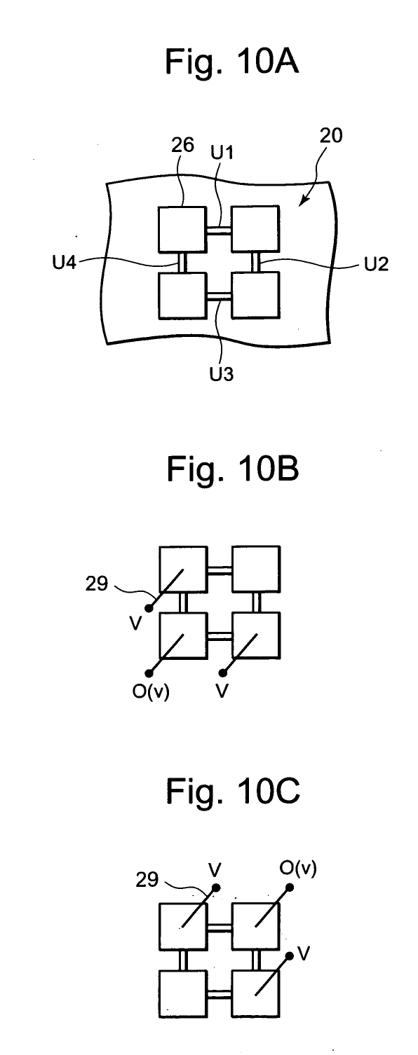

FIGS. 10A to 10C are top views showing a second exemplary embodiment of a semiconductor device according to the present invention. The first exemplary embodiment is an example in which four electrode pads are arranged on a straight line, whereas in a semiconductor device 20 of this embodiment, four electrode pads 26 are arranged in a matrix state of two by two. As shown in FIG. 10A, the four electrode pads 26 are connected so as to form an annulus via through-hole chains U1, U2, U3 and U4.

The measurement of the resistance of the through-hole chains U1, U2, U3 and U4 is performed in the same manner as described in the first embodiment. On that occasion, as shown in FIGS. 10B and 10C, three probes 29 are connected to their respective electrode pads 26. The voltage to the probe 29 in the middle is set at zero, the voltage to the probes 29 on both sides is simultaneously applied so that this voltage becomes V, and currents flowing through the probes 29 on both sides are measured. In this manner, the resistance R of U1, U2, U3 and U4 is found.

In the first exemplary embodiment, the electrode pads 16 are arranged in a single horizontal row. In the semiconductor device 20 of the second embodiment, the electrode pads 26 are arranged in a matrix state of two by two. For this reason, the area of a check pattern can be reduced and space savings becomes possible.

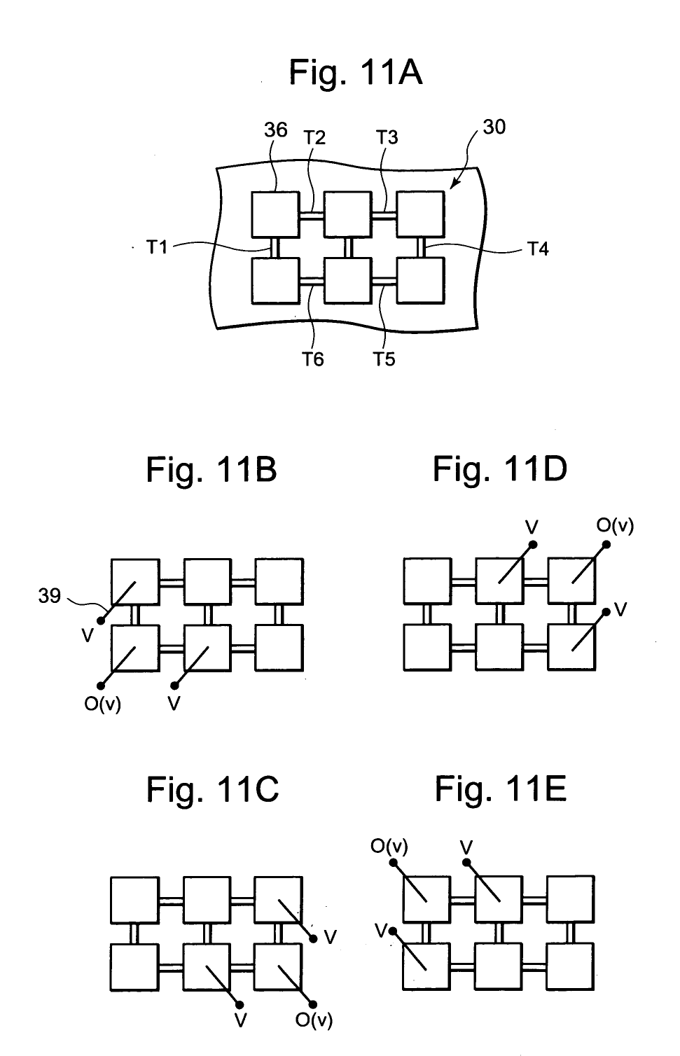

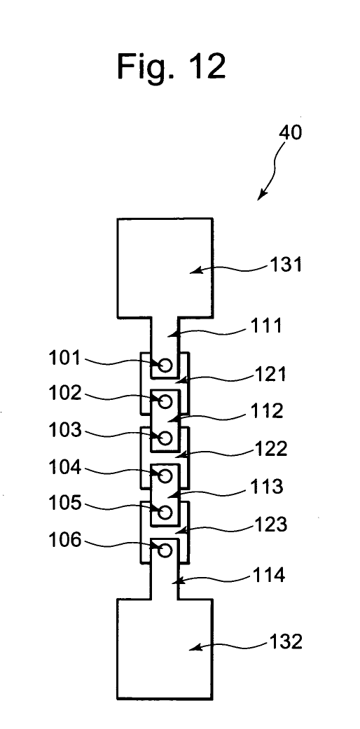

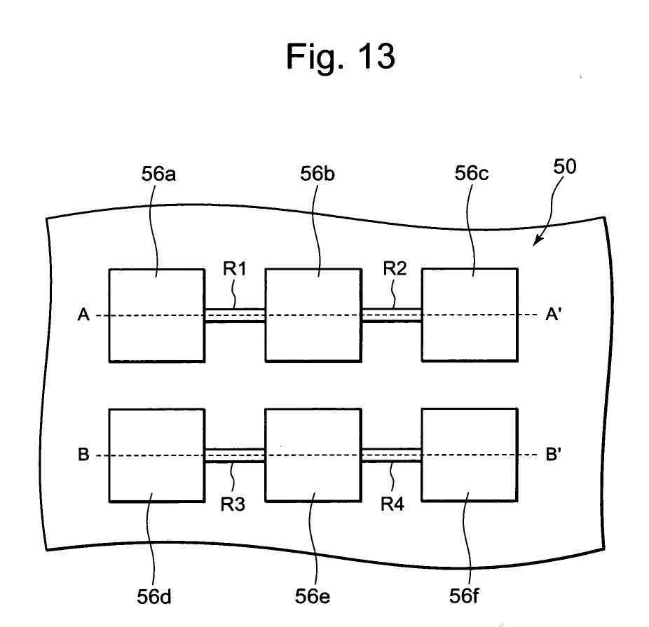

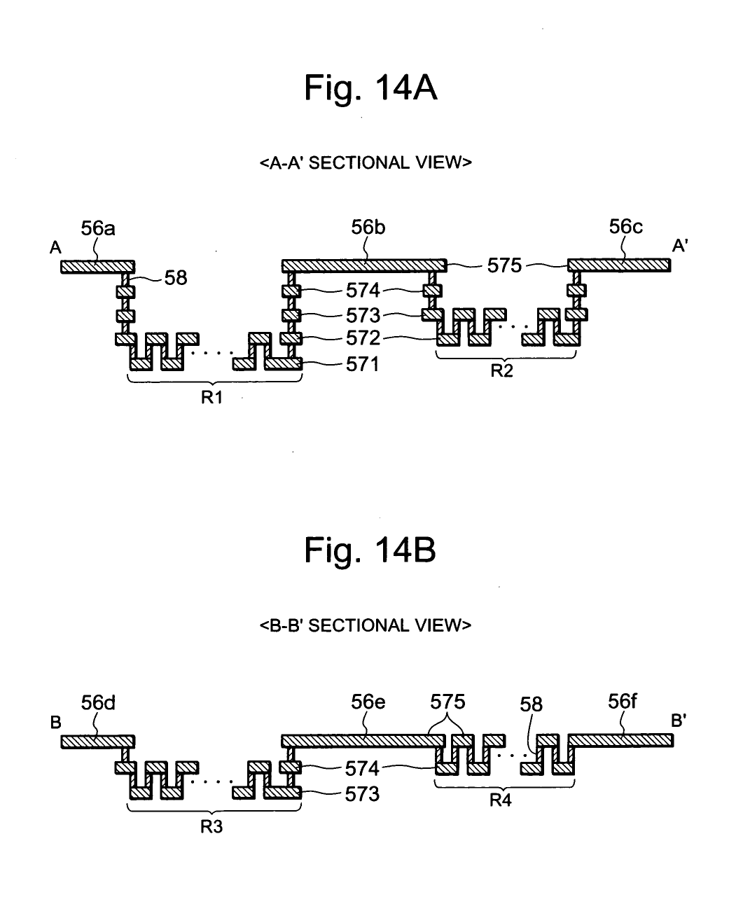

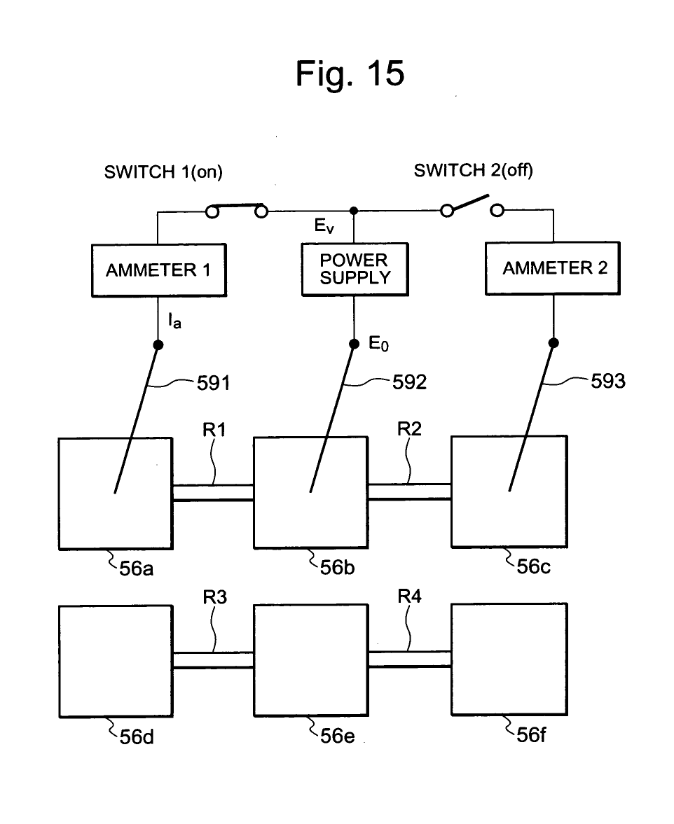

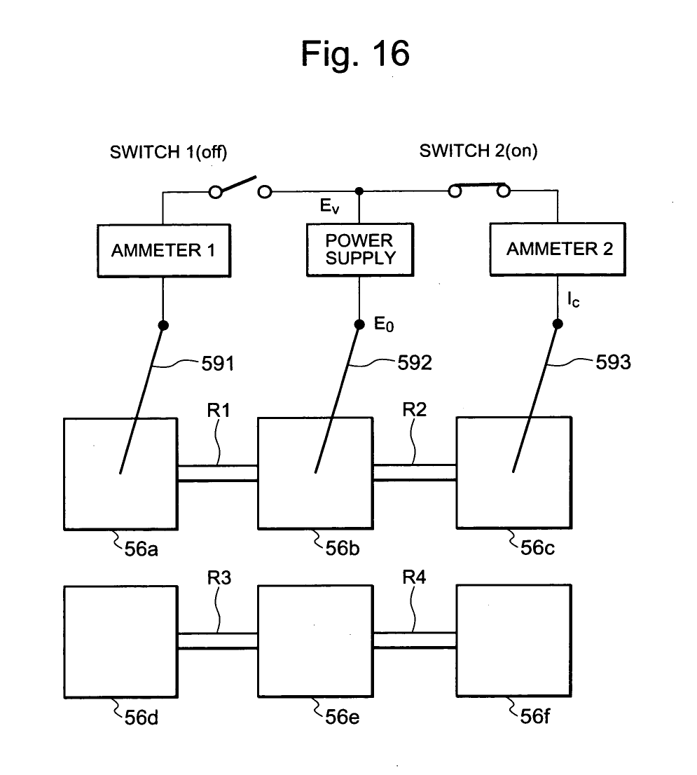

FIGS. 11A to 11E are top views showing a third exemplary embodiment of a semiconductor device according to the present invention. The first exemplary embodiment is an example in which four electrode pads are arranged on a straight line in a semiconductor device having a structure of four-layer aluminum interconnects and electrode pad layers. In contrast, in this embodiment, six electrode pads 36 are arranged in a matrix state of two by three in a semiconductor device 30 having a structure of six-layer aluminum interconnects and electrode pad layers. As shown in FIG. 11A, the six electrode pads 36 are connected so as to form an annulus via through-hole chains T1, T2, T3, T4, T5 and T6.

The measurement of the resistance of the through-hole chains T1, T2, T3, T4, T5 and T6 is performed in the same manner as described in the first embodiment. On that occasion, as shown in FIGS. 11B to 11D, three probes 39 are connected to the respective electrode pads 36. The voltage to the probe 39 in their middle is set at zero, the voltage to the probes 39 on both sides is simultaneously applied so that this voltage becomes V, and currents flowing through the probes 39 on both sides are measured. In this manner, the resistance R of T1, T2, T3, T4, T5 and T6 is found. An annular check pattern can be formed so that the same number of electrode pads as the number of interconnect layers is obtained.

The semiconductor device according to the present invention and the evaluation method thereof are not limited to the above-described embodiments and various modifications are possible. For example, in the embodiments, the description was given of a case where through-hole chains having different via layers are formed by connecting a plurality of through holes formed in different single via layers and interconnects provided in the upper part and lower part of the via layer. However, through-hole chains may be formed across a plurality of via layers of different layers. That is, the through-hole chains are such that a plurality of through holes formed in a plurality of via layers and interconnects provided in the upper part and lower part of the via layer are connected, and hence the through-hole chains have via layers that differ due to a difference in the number and combination of via layers. As a result of this, two through-hole chains having different via layers are annularly connected via electrode pads and, therefore, it is possible to simultaneously measure the resistance of the two through-hole chains having different via layers.

No matter how many electrode pads are formed, this is allowed so long as the number of electrode pads is three or more. Also, the number of probes used in resistance measurement is not limited to three.

Further, it is noted that Applicant's intent is to encompass equivalents of all claim elements, even if amended later during prosecution.

What is claimed is;:

1. A semiconductor device comprising:
a multilayer interconnect structure in which an interconnect layer and a via layer are alternately stacked; and
a plurality of through-hole chains formed by a plurality of through holes formed in the via layer and a plurality of interconnects provided in the through holes and in an upper part and a lower part of the via layer,
wherein the through-hole chains provided in different via layers are connected so as to form an annulus via electrode pads so that resistance of two through-hole chains provided in different via layers is simultaneously measurable by using the electrode pads.

2. The semiconductor device according to claim 1, wherein the through-hole chain of the plurality of through-hole chains is constructed by that the plurality of through holes formed in single via layers and interconnects provided in an upper part and a lower part of the via layer being connected to each other.

3. The semiconductor device according to claim 1, wherein the electrode pads are arranged in a matrix state, and are connected to form an annulus via the through-hole chains.

4. A method of evaluating a semiconductor device, comprising:
preparing first, second and third electrode pads circularly connected to each other via an interconnect layer and a via layer alternately stacked in a through hole to provide a through-hole chain;
supplying a first voltage with said first electrode pad;
supplying a second voltage with said second and third electrode pads; and
simultaneously measuring a resistance of a through hole-chain connected between the first and second electrode pads and a resistance of a through hole-chain connected between the first and third electrode pads.

5. A semiconductor device, comprising:
a plurality of wiring layers;
a plurality of via layers; and
a plurality of electrode pads circularly connected to each other through said wiring layers and said via layers.

6. The semiconductor device as claimed in claim 5, wherein a number of the via layers between first and second electrode pads of said plurality of electrode pads is different from a number of the via layers between the first electrode pad and a third electrode pad of said plurality of electrode pads.

7. The semiconductor device as claimed in claim 5, wherein a number of the wiring layers between first and second electrode pads of said plurality of electrode pads is different from and a number of the wiring layers between the first electrode pad and a third electrode pad of said plurality of electrode pads.

8. The semiconductor device as claimed in claim 5, wherein said electrode pads are arranged in a matrix.

9. The semiconductor device as claimed in claim 5, wherein said electrode pads are arranged in a single straight line.

10. The semiconductor device as claimed in claim 6, wherein a number of said electrode pads is six or more.

11. The semiconductor device as claimed in claim 5, wherein a number of said electrode pads is the same as a number of resistors defined as a conductive path between corresponding electrode pads.
